(19) United States
(12) Patent Application Publication
(10) Pub. No.: US 2025/0092520 A1
(43) Pub. Date: Mar. 20, 2025

(54) SEMICONDUCTOR MANUFACTURING APPARATUS AND PROCESS

(71) Applicant: ASM IP Holding B.V., Almere (NL)

(72) Inventors: Davide Proserpio, Zeist (NL); Dieter Pierreux, Pepingen (BE); Theodorus G.M. Oosterlaken, Oudewater (NL); Herbert Terhorst, Amersfoort (NL)

(21) Appl. No.: 18/889,183

(22) Filed: Sep. 18, 2024

Related U.S. Application Data
(60) Provisional application No. 63/539,124, filed on Sep. 19, 2023.

(51) Int. Cl. C23C 16/455; C23C 16/06; C23C 16/52

(52) U.S. Cl. CPC C23C 16/45561; C23C 16/06; C23C 16/45544; C23C 16/52

(57) ABSTRACT

In general, the various aspects of the technology of the present disclosure relate to semiconductor manufacturing apparatuses and processes which may comprise two or more accumulators connected in parallel to each other. The apparatus may have a solid-state precursor sublimator upstream from said two or more accumulators employed by the process.

### CROSS-REFERENCE TO RELATED APPLICATION(S)

This Application claims the benefit of U.S. Provisional Application 63/539,124 filed on Sep. 19, 2023, the entire contents of which are incorporated herein by reference.

### FIELD

In general, the various aspects of the technology of the present disclosure relate to semiconductor manufacturing apparatus and process.

### BACKGROUND

During processes such as Atomic Layer Deposition (ALD), Epitaxy, Plasma-enhanced chemical vapor deposition (PECVD), diffusion (annealing) and Chemical Vapor Deposition (CVD) precursors and other chemical compounds which may be in the form of a gas, liquid or solid are deposited onto or contacted with a workpiece. These chemical compounds are often stored in a container or storage vessel from where they are transported to the workpiece in the reaction chamber.

The ALD manufacturing process typically involves pulsing chemical compounds into the reaction chamber, allowing them to react with the substrate surface, and then purging the chamber before introducing the next chemical compounds.

In some systems, an accumulator may be used to store and deliver chemical compounds to the reaction chamber. The function of the accumulator is to increase the flow of chemical compounds to the reaction chamber.

These manufacturing processes may use a variety of different chemical compounds, each of them having particular parameters for optimal operation. The conditions of the manufacturing of the semiconductors may be adapted based on the chemical compounds that are used.

For instance, for the delivery of precursors to the reaction chamber, the flow rate of the precursor to the reactor chamber may be of importance and this flow rate may determine the throughput of the entire process. Different types of precursors may be characterized by having different flow rates, and while parameters such as the temperature and pressure of the system may be used to adapt the flow rate of particular precursors.

Therefore, there may be a need for further adaptations to the semiconductor manufacturing apparatus and process.

### SUMMARY

A first overview of various aspects of the technology of the present disclosure is given herein, after which specific embodiments will be described in more detail. This overview is meant to aid the reader in understanding the technological concepts more quickly, but it is not meant to identify the most important or essential features thereof, nor is it meant to limit the scope of the present disclosure, which is limited only by the claims.

An aspect of the present disclosure relates to a semiconductor manufacturing apparatus, the apparatus may comprise:
a reaction chamber of the semiconductor manufacturing process;
one or more gas inlets to said reaction chamber; and;
two or more accumulators connected to at least one of said one or more gas inlets.

In particular said two or more accumulators may be connected in parallel to each other.

By using two or more accumulators connected in parallel to each other it may be possible to make the manufacturing system more efficient, providing more flexibility to the system. For instance, while process gas is discharged from one of the accumulators, other accumulators can be charged with process gas. The parallel configuration of the accumulators therefore allows for them to be discharged one after the other and recharged while the others are discharged. This procedure allows the “burst flow” effect to continue even after a single accumulator is emptied.

More in particular said semiconductor manufacturing apparatus may comprise two accumulators connected in parallel to each other.

Furthermore, the flexibility of having a plurality of accumulators in parallel may allow them to be used separately but also as a single accumulator if this is required.

More in particular, the semiconductor manufacturing apparatus as disclosed herein may provide that said apparatus further comprises a solid-state precursor sublimator upstream from said two or more accumulators.

More in particular, the semiconductor manufacturing apparatus as disclosed herein may provide that the combined volume of said two or more accumulators ranges between 10 liters and 200 liters.

More in particular, the semiconductor manufacturing apparatus as disclosed herein may provide that the volume of each of said two or more accumulators is equal.

More in particular, the semiconductor manufacturing apparatus as disclosed herein may provide that the volume of at least two of said two or more accumulators may be different.

More in particular, the semiconductor manufacturing apparatus as disclosed herein provides that the conduct lines upstream and downstream from said two or more accumulators may comprise conduct line valves. More in particular said apparatus further may comprise one or more sensors for the real-time monitoring and detection of the open/closed status of said conduct line valves.

More in particular, the semiconductor manufacturing apparatus as disclosed herein may provide that said apparatus further comprises a controller comprising program instructions for:
accumulating a process gas in said two or more accumulators until each of said accumulators is at an accumulator pressure level which may be substantially greater than the pressure level in said reaction chamber; and
rapidly discharging said process gas from at least one of said two or more accumulators into said reaction chamber.

More in particular, the semiconductor manufacturing apparatus as disclosed herein provides that said process gas may comprise a precursor compound. More in particular said precursor compound may be a liquid or a solid precursor compound. More in particular said precursor compound may be a liquid or solid precursor comprising a metal or a metalloid. More in particular said metal may be selected from an alkaline metal, an alkaline earth metal, a transition metal, and a rare earth metal.

More in particular, the semiconductor manufacturing apparatus as disclosed herein provides that said precursor compound may be a homoleptic or heteroleptic precursor.

More in particular, the semiconductor manufacturing apparatus as disclosed herein may provide that said precursor compound includes at least one compound chosen from Titanium tetrachloride (TiCl₄), Vanadium tetrachloride (VCI₄), Molybdenum pentachloride (MoCl₅), Molybdenumdioxidichloride (MoO₂Cl₂), Niobiumpentachloride (NbCl₅), Tantalumpentachloride (TaCl₅), Aluminumtrichloride (AlCl₃), Hafniumtetrachloride (HfCl₄), Zirconiumtetrachloride (ZrCl₄), Tetrakis(ethylmethylamido)zirconium (TEMAZr), Tetrakis(ethylmethylamido)hafnium (TEMAHf), Trimethylborate (TMB), Fluorotriethoxysilane (FTES), Tetrakis-dimethylamino Titanium (TDMAT), Tetrakis-diethylamino (TDEAT), CuTMVS, Diethylsilane, and/or Triethylphosphate (TEPO).

The list of precursor compounds provided in the present disclosure is intended to be exemplary and not exclude other compounds falling within the scope of the claims. Other compounds that are functionally equivalent or structurally similar to those listed are also considered to be within the scope of the disclosed method and system. The disclosure encompasses all such variations and modifications that would be apparent to a person skilled in the art.

More in particular, the semiconductor manufacturing apparatus as disclosed herein may provide that said controller comprises program instructions for determining the open/closed status of conduct line valves on conduct lines upstream and downstream from said two or more accumulators. More in particular said controller may comprise program instructions for alternatingly accumulating and discharging process gas in and from said two or more accumulators wherein process gas may be accumulating in a first accumulator while process gas may be discharged from a second accumulator, and wherein process gas may be accumulating in a second accumulator when process gas is discharged from said first accumulator.

More in particular, the semiconductor manufacturing apparatus as disclosed herein provides that said semiconductor manufacturing apparatus is a vertical furnace.

More in particular, the semiconductor manufacturing apparatus as disclosed herein provides that said vertical furnace comprises a reaction chamber configured for chemical vapor deposition (CVD) or atomic layer deposition (ALD). More in particular, said reaction chamber is configured for receiving batch of wafers accommodated in a wafer boat.

In a further aspect, the present disclosure provides in a method for the delivery of process gas to a reaction chamber for the manufacturing of semiconductor, the method comprising the steps of:
accumulating a process gas in two or more accumulators until each of said accumulators is at an accumulator pressure level which may be substantially greater than the pressure level in said reaction chamber; and
rapidly discharging said process gas from at least one of said two or more accumulators into said reaction chamber.

In particular said two or more accumulators are connected in parallel to each other.

More in particular, the method as disclosed herein provides that said process gas comprises a precursor compound. More in particular said precursor compound may be a liquid or a solid precursor compound. More in particular said precursor compound may be a liquid or solid precursor comprising a metal or a metalloid. More in particular said metal may be selected from an alkaline metal, an alkaline earth metal, a transition metal, and a rare earth metal.

More in particular, the method as disclosed herein provides that said precursor compound may be a homoleptic or heteroleptic precursor.

More in particular, the method as disclosed herein provides that said precursor compound may be chosen from Titanium tetrachloride (TiCl₄), Vanadium tetrachloride (VCl₄), Molybdenum pentachloride (MoCl₅), Molybdenumdioxidichloride (MoO₂Cl₂), Niobiumpentachloride (NbCl₅), Tantalumpentachloride (TaCl₅), Aluminumtrichloride (AlCl₃), Hafniumtetrachloride (HfCl₄), Zirconiumtetrachloride (ZrCl₄), Tetrakis(ethylmethylamido)zirconium (TEMAZr) or Tetrakis(ethylmethylamido)hafnium (TEMAHf), Trimethylborate (TMB), Fluorotriethoxysilane (FTES), Tetrakis-dimethylamino Titanium (TDMAT), Tetrakis-diethylamino (TDEAT), CuTMVS, Diethylsilane, and/or Triethylphosphate (TEPO).

More in particular, the method as disclosed herein provides that the steps of accumulating and discharging said process gas occur alternatingly, thereby accumulating process gas in a first accumulator while process gas is discharged from a second accumulator, and accumulating process gas in a second accumulator when process gas is discharged from said first accumulator.

More in particular, the method as disclosed herein provides that said method may be employed in a vertical furnace.

More in particular, the method as disclosed herein provides that said method may be an ALD method.

### BRIEF DESCRIPTION OF THE DRAWINGS

The following description of the figures relate to specific embodiments of the disclosure which are merely exemplary in nature and not intended to limit the present teachings, their application or uses.

FIG. 1 schematically shows an exemplary system as described herein.

FIGS. 2A, B and C show the exemplary system of FIG. 1 in various configurations.

FIGS. 3A and 3B show graphs of the pressure in the accumulators (A) and the flow rate to the reaction chamber (B).

### DETAILED DESCRIPTION

In the following detailed description, the technology underlying the present disclosure will be described by means of different aspects thereof. It will be readily understood that the aspects of the present disclosure, as generally described herein, and illustrated in the figures, can be arranged, substituted, combined, and designed in a wide variety of different configurations, all of which are explicitly contemplated and make part of this disclosure. This description is meant to aid the reader in understanding the technological concepts more easily, but it is not meant to limit the scope of the present disclosure, which is limited only by the claims.

Reference throughout this specification to “one embodiment” or “an embodiment” means that a particular feature, structure, or characteristic described in connection with the embodiment is included in at least one embodiment of the present disclosure. Thus, appearances of the phrases “in one embodiment” or “in an embodiment” in various places throughout this specification are not necessarily all referring to the same embodiment.

As used herein, the terms “comprising”, “comprises” and “comprised of” as used herein are synonymous with “including”, “includes” or “containing”, “contains”, and are inclusive or open-ended and do not exclude additional, non-recited members, elements, or method steps. The terms “comprising”, “comprises” and “comprised of” when referring to recited members, elements or method steps also include embodiments which “consist of” said recited members, elements, or method steps. The singular forms “a”, “an”, and “the” include both singular and plural referents unless the context clearly dictates otherwise.

As used herein, relative terms, such as “left,” “right,” “front,” “back,” “top,” “bottom,” “over,” “under,” etc., are used for descriptive purposes and not necessarily for describing permanent relative positions. It is to be understood that such terms are interchangeable under appropriate circumstances and that the embodiment as described herein are capable of operation in other orientations than those illustrated or described herein unless the context clearly dictates otherwise.

Objects described herein as being “adjacent” to each other reflect a functional relationship between the described objects, that is, the term indicates the described objects must be adjacent in a way to perform a designated function which may be a direct (i.e. physical) or indirect (i.e. close to or near) contact, as appropriate for the context in which the phrase is used.

Objects described herein as being “connected” or “coupled” reflect a functional relationship between the described objects, that is, the terms indicate the described objects must be connected in a way to perform a designated function which may be a direct or indirect connection in an electrical or nonelectrical (i.e. physical) manner, as appropriate for the context in which the term is used.

As used herein, the term “substantially” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness may in some cases depend on the specific context. However, generally speaking the nearness of completion will be so as to have the same overall result as if absolute and total completion were obtained. The use of “substantially” is equally applicable when used in a negative connotation to refer to the complete or near complete lack of an action, characteristic, property, state, structure, item, or result.

As used herein, the term “about” is used to provide flexibility to a numerical value or range endpoint by providing that a given value may be “a little above” or “a little below” said value or endpoint, depending on the specific context. Unless otherwise stated, use of the term “about” in accordance with a specific number or numerical range should also be understood to provide support for such numerical terms or range without the term “about”. For example, the recitation of “about 30” should be construed as not only providing support for values a little above and a little below 30, but also for the actual numerical value of 30 as well.

The recitation of numerical ranges by endpoints includes all numbers and fractions subsumed within the respective ranges, as well as the recited endpoints. Furthermore, the terms first, second, third and the like in the description and in the claims, are used for distinguishing between similar elements and not necessarily for describing a sequential or chronological order, unless specified. It is to be understood that the terms so used are interchangeable under appropriate circumstances and that the embodiments of the disclosure described herein are capable of operation in other sequences than described or illustrated herein.

Reference in this specification may be made to devices, structures, systems, or methods that provide “improved” performance (e.g. increased or decreased results, depending on the context). It is to be understood that unless otherwise stated, such “improvement” is a measure of a benefit obtained based on a comparison to devices, structures, systems, or methods in the prior art. Furthermore, it is to be understood that the degree of improved performance may vary between disclosed embodiments and that no equality or consistency in the amount, degree, or realization of improved performance is to be assumed as universally applicable.

In addition, embodiments of the present disclosure may include hardware, software, and electronic components or modules that, for purposes of discussion, may be illustrated and described as if the majority of the components were implemented solely in hardware. However, one of ordinary skill in the art, and based on a reading of this detailed description, would recognize that, in at least one embodiment, the electronic based aspects of the present disclosure may be implemented in software (e.g., instructions stored on non-transitory computer-readable medium) executable by one or more processing units, such as a microprocessor and/or application specific integrated circuits. As such, it should be noted that a plurality of hardware and software-based devices, as well as a plurality of different structural components may be utilized to implement the technology of the present disclosure. For example, “servers” and “computing devices” described in the specification can include one or more processing units, one or more computer-readable medium modules, one or more input/output interfaces, and various connections connecting the components.

An overview of various aspects of the technology of the present disclosure is given hereinbelow, after which specific embodiments will be described in more detail. This overview is meant to aid the reader in understanding the technological concepts more quickly, but it is not meant to identify the most important or essential features thereof, nor is it meant to limit the scope of the present disclosure, which is limited only by the claims. When describing specific embodiments, reference is made to the accompanying drawings, which are provided solely to aid in the understanding of the described embodiment.

Disclosed herein are microfabrication methods and systems where for the delivery of chemical compounds, and in particular precursors, to the reaction chamber two or more accumulators connected in parallel to each other are used. Typically, due to space constraints, a single accumulator per reaction chamber is used in semiconductor manufacturing systems and methods. An accumulator may be used in microfabrication processes and systems to ensure increased and controlled delivery of chemical compounds to the reaction chamber. An accumulator enables precise pulsing control, ensuring that only the desired amount of chemical compound is introduced during each step.

It has now been found that considerable improvements to microfabrication methods and systems can be achieved by introducing into the system two or more accumulators connected in parallel to each other. Although the use of multiple accumulators renders the systems and methods more complex (e.g. requiring more conduct lines, valves and controllers), it has been found that two or more accumulators connected in parallel to each other can achieve more uniform reaction conditions, facilitate the management of multiple chemical compounds and provide more process flexibility, accommodating variations in flow rates and adapting to different chemistries, enhancing the overall efficiency and control of the microfabrication system and process. Also, the use of two or more accumulators connected in parallel to each helps in reducing the pulsing frequency, thereby further improving the overall process efficiency.

Therefore, an aspect of the present disclosure relates to a semiconductor manufacturing apparatus, the apparatus may comprise:
a reaction chamber of the semiconductor manufacturing process;
one or more gas inlets to said reaction chamber; and;
two or more accumulators connected to at least one of said one or more gas inlets.

In particular said two or more accumulators may be connected in parallel to each other.

More in particular said semiconductor manufacturing apparatus may comprise two accumulators connected in parallel to each other.

As referred to herein, the term “chemical compound” refers to the chemical compounds used in semiconductor manufacturing techniques such as Chemical Vapor Deposition (CVD), Atomic Layer Deposition (ALD), Plasma-enhanced chemical vapor deposition (PECVD), diffusion (annealing) and epitaxy. The chemical compounds may be chosen based on the particular process to be performed in the reaction chamber. The chemical compounds may be in gaseous, liquid or solid form and may for instance be reactants such as precursors.

In a particular embodiment the chemical compounds as referred to herein are precursor compounds. More in particular, the method and systems according to the present disclosure provides that the chemical compound may be a precursor. More in particular, said precursor may be a liquid or a solid precursor. During the typical semiconductor manufacturing process the substrate undergoes a plurality of deposition cycles which typically comprise a precursor pulse and a reactant pulse. After a pre-determined amount of deposition cycles, the method ends. During such a precursor pulse vaporized liquid or solid precursor may be transported to the reaction chamber. This may be done by using a carrier gas to generate a process gas comprising the carrier gas and vaporized precursor which may be subsequently provided to the reaction chamber. This typically occurs in a pulse train where at specified time intervals transport of the precursor to the reaction chamber occurs.

As used herein, the term “process gas” refers to the gas comprising the chemical compound used in the semiconductor manufacturing apparatus. Often, a liquid or solid chemical compound may be used in the semiconductor manufacturing process or apparatus and this chemical compound may be vaporized (evaporated for liquid precursor or sublimated for solid state precursor) to be transported in gas form to the reaction chamber. Besides the chemical compound used in the semiconductor manufacturing apparatus, the process gas may further comprise a carrier gas such as N₂, Ar, He, or combinations thereof.

As referred to herein, the term “process chamber” or “reactor chamber” refers to the reaction chamber that may be coupled to a chemical compound delivery system. The reaction chamber may include an inner volume with a substrate support disposed therein for supporting a substrate to be processed (such as a semiconductor wafer or the like). The reaction chamber may be configured for ALD, CVD, or the like. The reaction chamber may further comprise a processing system comprising additional components, for example, one or more radiofrequency or other energy sources for generating a plasma within the inner volume or for providing radio-frequency bias to a substrate disposed on the substrate support.

As referred to herein, the term “accumulator” refers to a component that stores chemical compounds such as precursor gases and facilitates their controlled delivery to the reaction chamber. The accumulator acts as a buffer, ensuring a stable and continuous supply of chemical compounds during the deposition process.

Furthermore, as referred to herein, “parallel connection” or “connected in parallel” refers to a configuration in which two or more accumulators are connected side by side, sharing a common inlet and outlet point. In this arrangement, the accumulators are interconnected in parallel, allowing material to flow simultaneously to and through each accumulator before reaching the reaction chamber.

The use of two or more accumulators connected in parallel to each other allows to load chemical compounds in parallel while the deposition may be ongoing, ensuring continuous operation and reducing process downtime. This setup enables one accumulator to deliver chemical compounds while the other may be being recharged or refilled.

Consequently, the semiconductor manufacturing apparatus as disclosed herein allows for an improved regulation of the chemical compound flow to the reaction chamber, allowing for an increased flow while maintaining consistent concentration levels. It enhances process control, promotes uniform film growth, and enables the management of multiple chemical compounds in microfabrication systems.

Moreover, the use of two or more accumulators that are connected in parallel to each other may allow for the deposition of different materials in an alternating manner. The use of multiple accumulators connected in parallel can be utilized to accumulate and deliver different chemical compounds, allowing for rapid and controlled switching between the deposition of different chemical compounds.

Also, by using a semiconductor manufacturing apparatus or system where two or more accumulators are connected in parallel to each other, the system as disclosed herein may become much more flexible. It may allow for microfabrication processes requiring the use of chemical compound combinations that are incompatible with each other or that need to be kept separate until they reach the reaction chamber. Multiple accumulators can be employed to store and deliver different chemical compounds independently allowing for a precise control over chemical compound mixing and preventing premature reactions or unwanted chemical reactions before entering the reaction chamber.

More in particular, the semiconductor manufacturing apparatus as disclosed herein provides that said apparatus may further comprise a solid-state precursor sublimator upstream from said two or more accumulators.

As referred to herein, the term “precursor sublimator” refers to the component in the microfabrication system where solid chemical compounds such as precursor materials are converted into a vapor phase by applying heat or energy. The vaporized chemical compound, preferably precursor material, may then be transported through the two or more accumulators to the reaction chamber. Typically, the chemical compounds are stored in storage vessels and transferred to the sublimator when needed in the deposition process. Separating the storage of the chemical compounds from the sublimator helps ensure proper handling, containment, and preservation of the properties of the chemical compounds, while allowing for controlled and precise deposition in the manufacturing process.

More in particular, the semiconductor manufacturing apparatus as disclosed herein may provide that the combined volume of said two or more accumulators ranges between 0.10 liters and 200 liters, preferably between 1 liter and 200 liters, and more preferably between 10 liters and 200 liters. More in particular the combined volume of said two or more accumulators ranges between 10 liters and 100 liters. The combined volume of said two or more accumulators may preferably be 10 liters, 15 liters, 20 liters, 30 liters, 40 liters, 50 liters, 60 liters, 70 liters, 80 liters, 90 liters, or 100 liters. Typically, the combined volume of the two or more accumulators may be about 10% of the volume of the reaction chamber.

More in particular, the semiconductor manufacturing apparatus as disclosed herein provides that the volume of each of said two or more accumulators may be equal.

The use of two or more accumulators with equal volumes in a system offers several advantages and functionalities. By employing accumulators of the same size, the system ensures balanced chemical compound delivery and enhances redundancy. The parallel connection of accumulators with equal volumes enables simultaneous operation, dividing the chemical compound flow evenly between them. This redundancy may help maintain process continuity even if one accumulator experiences an issue or requires maintenance, minimizing downtime and interruptions in the deposition process. Additionally, equal-volume accumulators may provide increased flow capacity, allowing for higher chemical compound throughput when compared to a single accumulator. This can be beneficial in applications where a higher deposition rate or larger-scale processing is desired. The use of multiple accumulators with equal volumes may enhance system reliability, process robustness, and/or overall efficiency.

Alternatively, the semiconductor manufacturing apparatus as disclosed herein provides that the volume of at least two of said two or more accumulators may be different.

The use of two or more accumulators with varying volumes may enhance the flexibility and control of the system. By incorporating accumulators of different sizes or capacities, the system may gain the ability to handle varying volumes of chemical compounds and adapt to specific process requirements. Larger accumulators can accommodate higher quantities, allowing for extended operation before requiring refilling or recharging. On the other hand, smaller accumulators offer advantages in situations where precise and rapid switching between different precursor materials or concentrations is necessary. The use of multiple accumulators with different volumes may enable fine-tuning of precursor delivery, ensures a continuous and stable flow, and/or optimizes the process for efficient and reliable deposition. This flexibility facilitates adjustments to deposition parameters, accommodates changes in chemical compound availability, and enables customization of the process based on specific material requirements or experimental needs. Ultimately, employing multiple accumulators with varying volumes may add versatility to the system, contributing to improved control and adaptability in the deposition process.

More in particular, the semiconductor manufacturing apparatus as disclosed herein may provide that the conduct lines upstream and downstream from said two or more accumulators comprise conduct line valves. More in particular said apparatus may further comprise one or more sensors for the real-time monitoring and detection of the open/closed status of said conduct line valves.

A “conduct line” provides connections between the different components of the semiconductor manufacturing apparatus, e.g. connecting the accumulators to the reaction chamber. The conduct lines therefore conduct the chemical compounds through the semiconductor manufacturing apparatus to the reaction chamber.

As used herein the term “conduct line valve” refers to the valve that controls the flow of chemical compounds to and from the accumulators and to and from the reaction chamber. The conduct line valve may be positioned in proximity of the accumulators, in particular downstream and/or upstream from the accumulators on a yet unbranched part of the conduct line. Indeed, while the conduct line may be branched between the accumulators and the reaction chamber (e.g. a branch to a venting system), the conduct line valve may be positioned in proximity of the accumulators downstream and/or upstream from the accumulators on an unbranched part of the conduct line.

The flow rate of said chemical compound through said conduct line can be measured using flow meters, such as a mass flow meter (MFM), positioned on said conduct line. The flow meter may determine the flow rate of the chemical compound through the conduct line.

Also, to allow purging of the conduct lines, accumulators and/or the reaction chamber, a purge valve may be used on a purge line. The purging can be conducted with inert gas in between chemical compound pulses in order to clean the reaction chamber and remove any chemical compound that is unattached to the surface after that particular pulse. In a particular embodiment the charging of at least one of said accumulators may occur during the purge time, during the reactant pulse time and/or during the reactant purge time.

More in particular, the semiconductor manufacturing apparatus as disclosed herein may provide that said apparatus further comprises high conduct lines between said sublimator and said two or more accumulators.

High conduct lines in the context of this disclosure refer to conduct lines that allow for high flow rates of chemical compounds to pass through the conduct lines. Typical flow rates for high conduct lines range from a few hundred sccm to several slm. It should be noted that for both high and low conductance lines the same flow rates can be obtained. The difference is the pressure drop built over the line for the same flow rate.

More in particular, the semiconductor manufacturing apparatus as disclosed herein may provide that said apparatus further comprises a controller comprising program instructions for:
accumulating a process gas in said two or more accumulators until each of said accumulators is at an accumulator pressure level which may be substantially greater than the pressure level in said reaction chamber; and
rapidly discharging said process gas from at least one of said two or more accumulators into said reaction chamber.

More in particular, the system according to the present disclosure provides that said controller or said system controller may be configured to display information regarding the accumulation and discharging of process gas from each of said accumulators on a graphical user interface (GUI), wherein said controller or said system controller may preferably be further configured to generate a warning/alarm message on said GUI when an error occurs during the operation of said semiconductor manufacturing process or apparatus.

A “controller” may be coupled to various components of the processing system for controlling the operation thereof. The controller generally comprises a central processing unit (CPU), a memory, and support circuits for the CPU. The controller may control the processing system directly, or via computers (or controllers) associated with a particular reaction chamber and/or the support system components. The controller may be one of any form of general-purpose computer processor that can be used in an industrial setting for controlling various chambers and sub-processors. The memory, or computer-readable medium of the CPU may be one or more of readily available memory such as random-access memory (RAM), NAND memory, read only memory (ROM), floppy disk, hard disk, flash, or any other form of digital storage, local or remote. The support circuits are coupled to the CPU for supporting the processor in a conventional manner. These circuits include cache, power supplies, clock circuits, input/output circuitry and subsystems, and the like. Methods as described herein may be stored in the memory as software routine that may be executed or invoked to control the operation of the processing system in the manner described herein. The software routine may also be stored and/or executed by a second CPU that may be remotely located from the hardware being controlled by the CPU.

More in particular, the semiconductor manufacturing apparatus as disclosed herein provides that said process gas comprises a precursor compound. More in particular said precursor compound may be a liquid or a solid precursor compound. More in particular said precursor compound may be a liquid or solid precursor comprising a metal or a metalloid. More in particular said metal may be selected from an alkaline metal, an alkaline earth metal, a transition metal, and a rare earth metal.

More in particular, the semiconductor manufacturing apparatus as disclosed herein provides that said precursor compound may be a homoleptic or heteroleptic precursor.

In particular, in the methods and systems according to the present disclosure the precursor may be a solid precursor comprising a metal or a metalloid. More particularly, said metal may be selected from an alkaline metal, an alkaline earth metal, a transition metal, a rare earth metal or a combination thereof. More particularly, said metalloid, an element that has properties that are intermediate between those of metals and nonmetals, may be silicon, boron, germanium, arsenic, antimony and/or tellurium. The solid precursor may also comprise one or more ligands, the one or more ligands being selected from H, halogens, alkyls, alkenyls, alkynes, carbonyls, dienyls, beta-diketonates, substituted or unsubstituted cyclodienyls, substituted or unsubstituted aryls or a combination thereof. Suitable halogens include F, Br, Cl, and/or I. Suitable alkyls, alkenyls, alkynes, dienyls, and cyclodienyls are typically C1 to C8 compounds. Suitable substituents on the cyclodienyls and aryls include C1 to C3 alkyls. Suitable beta-diketonates include 1,1,1,5,5,5-hexafluoropentane-2,4-dionate (hfac) and/or 2,4-pentanedione (hacac). In particular embodiments the solid precursor may be a homoleptic chemical compound (a metal compound where all ligands are identical) or a heteroleptic chemical compound (a metal compound having two or more different types of ligands). In further particular embodiments the solid precursor comprises a metal-carbon bond. In further particular embodiments the solid precursor comprises a pi complex.

More in particular, the semiconductor manufacturing apparatus as disclosed herein provides that said solid precursor compound may be chosen from Titanium tetrachloride (TiCl₄), Vanadium tetrachloride (VCl₄), Molybdenum pentachloride (MoCl₅), Molybdenumdioxidichloride (MoO₂Cl₂), Niobiumpentachloride (NbCl₅), Tantalumpentachloride (TaCl₅), Aluminumtrichloride (AlCl₃), Hafniumtetrachloride (HfCl₄), Zirconiumtetrachloride (ZrCl₄).

In particular, in the methods and systems according to the present disclosure the precursor may be a liquid precursor comprising a metal, more particularly, said metal may be selected from an alkaline metal, an alkaline earth metal, a transition metal, a rare earth metal or a combination thereof. The liquid precursor may also comprise one or more ligands, the one or more ligands being selected from H, halogens, alkyls, alkenyls, alkynes, carbonyls, dienyls, beta-diketonates, substituted or unsubstituted cyclodienyls, substituted or unsubstituted aryls or a combination thereof. Suitable halogens include F, Br, Cl, and/or I. In particular embodiments the liquid precursor may be a homoleptic chemical compound (a metal compound where all ligands are identical) or a heteroleptic chemical compound (a metal compound having two or more different types of ligands). In further particular embodiments the liquid precursor comprises a metal-carbon bond. In further particular embodiments the liquid precursor comprises a pi complex. Exemplary liquid precursors are, Tetrakis(ethylmethylamido)zirconium (TEMAZr), tetrakis-ethylmethylaminohafnium (TEMAHf), Trimethylborate (TMB), Fluorotriethoxysilane (FTES), Tetrakis-dimethylamino Titanium (TDMAT), Tetrakis-diethylamino (TDEAT), CuTMVS, Diethylsilane, and/or Triethylphosphate (TEPO). The list of precursor compounds provided in the present disclosure is intended to be exemplary and not exclude other compounds falling within the scope of the claims. Other compounds that are functionally equivalent or structurally similar to those listed are also considered to be within the scope of the disclosed method and system. The disclosure encompasses all such variations and modifications that would be apparent to a person skilled in the art.

More in particular, the semiconductor manufacturing apparatus as disclosed herein provides that said liquid precursor compound may be Tetrakis(ethylmethylamido)hafnium (TEMAHf) and/or Tetrakis(ethylmethylamido)zirconium (TEMAZr), Trimethylborate (TMB), Fluorotriethoxysilane (FTES), Tetrakis-dimethylamino Titanium (TDMAT), Tetrakis-diethylamino (TDEAT), CuTMVS, Diethylsilane, and/or Triethylphosphate (TEPO).

More in particular, the semiconductor manufacturing apparatus as disclosed herein provides that said controller comprises program instructions for determining the open/closed status of conduct line valves on conduct lines upstream and downstream from said two or more accumulators. More in particular said controller comprises program instructions for alternatingly accumulating and discharging process gas in and from said two or more accumulators wherein process gas may be accumulating in a first accumulator while process gas is discharged from a second accumulator, and wherein process gas may be accumulating in a second accumulator when process gas is discharged from said first accumulator.

More in particular, the semiconductor manufacturing apparatus as disclosed herein may provide that said semiconductor manufacturing apparatus is a vertical furnace.

More in particular, the semiconductor manufacturing apparatus as disclosed herein may provide that said vertical furnace comprises a reaction chamber configured for chemical vapor deposition (CVD) or atomic layer deposition (ALD). More in particular, said reaction chamber may be configured for receiving batch of wafers accommodated in a wafer boat.

As used herein, the term “vertical furnace” refers to type of manufacturing apparatus that is used for depositing thin films of material onto substrates with precise control. Vertical furnaces or reactors may be used for oxidation, diffusion, annealing, chemical vapor deposition (CVD) and atomic layer deposition (ALD). A vertical furnace typically includes a reaction chamber delimiting a process region. The reaction chamber may be configured for ALD, CVD, or the like and may preferably be a long quartz or silicon carbide reaction chamber. A batch of wafers, typically accommodated in a wafer boat placed on a pedestal for support and thermal isolation, are vertically inserted into the reaction chamber. The reaction chamber may include an inlet and an outlet for process gas and may be surrounded by one or more heating elements.

Especially for vertical furnaces where large batches of wafers are processed, the use of two or more accumulators connected in parallel to each other may provide significant improvements to the microfabrication methods and systems.

In a further aspect, the present disclosure provides in a method for the delivery of process gas to a reaction chamber for the manufacturing of semiconductor, the method comprising the steps of:
accumulating a process gas in two or more accumulators until each of said accumulators is at an accumulator pressure level which may be substantially greater than the pressure level in said reaction chamber; and
rapidly discharging said process gas from at least one of said two or more accumulators into said reaction chamber.

In particular said two or more accumulators are connected in parallel to each other.

More in particular, the method as disclosed herein provides that said process gas comprises a precursor compound. More in particular said precursor compound may be a liquid or a solid precursor compound. More in particular said precursor compound may be a liquid or solid precursor comprising a metal or a metalloid. More in particular said metal may be selected from an alkaline metal, an alkaline earth metal, a transition metal, and a rare earth metal.

More in particular, the method as disclosed herein provides that said precursor compound may be a homoleptic or heteroleptic precursor.

More in particular, the method as disclosed herein provides that said precursor compound may be chosen from Titanium tetrachloride (TiCl₄), Vanadium tetrachloride (VCl₄), Molybdenum pentachloride (MoCl₅), Molybdenumdioxidichloride (MoO₂Cl₂), Niobiumpentachloride (NbCl₅), Tantalumpentachloride (TaCl₅), Aluminumtrichloride (AlCl₃), Hafniumtetrachloride (HfCl₄), Zirconiumtetrachloride (ZrCl₄), Tetrakis(ethylmethylamido)zirconium (TEMAZr) or Tetrakis(ethylmethylamido)hafnium (TEMAHf), Trimethylborate (TMB), Fluorotriethoxysilane (FTES), Tetrakis-dimethylamino Titanium (TDMAT), Tetrakis-diethylamino (TDEAT), CuTMVS, Diethylsilane, and/or Triethylphosphate (TEPO).

More in particular, the method as disclosed herein provides that the steps of accumulating and discharging said process gas occur alternatingly, thereby accumulating process gas in a first accumulator while process gas may be discharged from a second accumulator, and accumulating process gas in a second accumulator when process gas may be discharged from said first accumulator.

More in particular, the method as disclosed herein provides that said method is employed in a vertical furnace.

More in particular, the method as disclosed herein provides that said method may be an ALD method. In ALD systems the use of two or more accumulators connected in parallel to each other may be especially convenient for precursors having low vapor pressure (both liquid and solid), for which the temperature cannot be increased because of limitations related e.g. to the decomposition of the precursor at high temperature (or any other thermal budget limitation).

Another aspect of the present disclosure relates to one or more non-transitory computer readable media encoded with a computer program, the computer program comprising instructions that, when executed by one or more computers, cause the one or more computers to perform operations for accumulating and/or discharging process gas in and/or from said two or more accumulators.

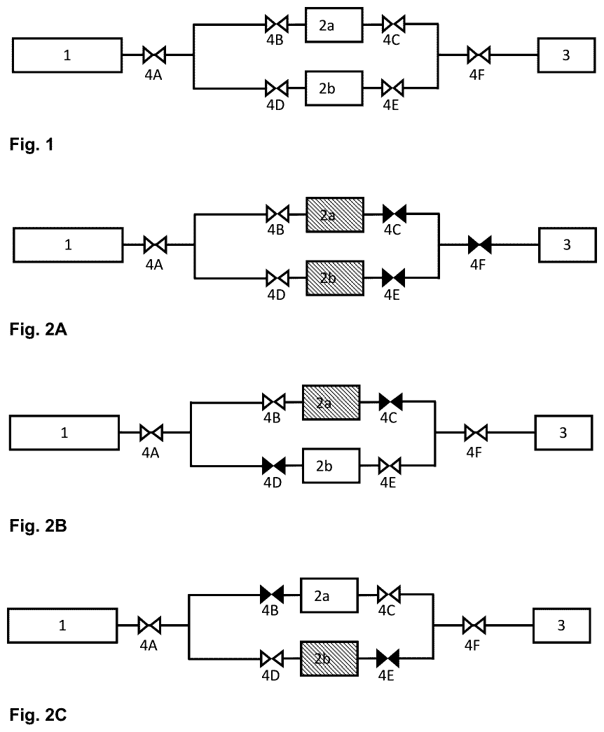

An exemplary system as described herein is shown in FIG. 1. FIG. 1 illustrates a system in accordance with yet additional exemplary embodiments of the disclosure. The system can be used to perform a method as described herein and/or form a structure or device portion as described herein. In the illustrated example of an ALD system (similar configurations can be applied on other semiconductor manufacturing systems), the system may include a sublimator (1) fluidically connected to a first accumulator (2a) and a second accumulator (2b) through conduct lines. The first accumulator (2a) and the second accumulator (2b) may be connected in parallel to each other. The first accumulator (2a) and the second accumulator (2b) may be further fluidically connected to the reaction chamber (3). The flow through the conduct is controlled by manifold valves (4A-F).

FIGS. 2A, B and C shows a system similar to FIG. 1 in three consecutive configurations. First, in FIG. 2A by opening valves 4A, 4B and 4D and closing valves 4C, 4E and 4F process gas flows from the sublimator to both accumulators thereby accumulating in both the first accumulator (2a) and the second accumulator (2b). In FIG. 2B valves 4A, 4B, 4E and 4F are opened and valves 4C and 4D are closed. As a result, process gas remains accumulated in the first accumulator (2a) while process gas is discharged from the second accumulator (2b) towards the reaction chamber (3). When process gas in the second accumulator (2b) is depleted, the configuration is switched to the one in FIG. 2C where valves 4A, 4C, 4D and 4F are opened and valves 4B and 4E are closed. As a result, process gas starts accumulating in the second accumulator (2b) while process gas is discharged from the second accumulator (2a) towards the reaction chamber (3). The configuration can be switched between FIG. 2B and FIG. 2C in order to maintain a continuous flow of process gas to the reaction chamber (3).

Also, to allow purging of the conduct lines, accumulators and/or the reaction chamber, purge valves may be used on a purge line. The purging can be conducted with inert gas. In an ALD process typically after each precursor pulse step there is a purge step, which is used to clean the system and remove any precursor that is unattached to the surface after that particular pulse.

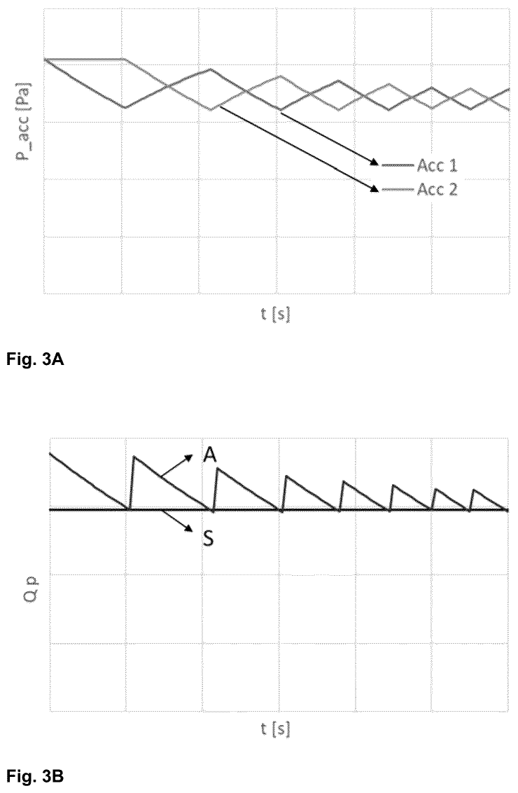

FIG. 3A shows a graph of the pressure in a first and a second accumulator starting with the discharge of process gas from the first accumulator, followed by the discharge from the second accumulator while at the same time process gas is accumulated in the first accumulator and vice versa. This procedure is repeated several times, each time alternating between the first accumulator and the second accumulator. FIG. 3B shows a graph of the flow rate (Qp) of process gas to the reaction chamber and compares the procedure where two accumulators alternate (A) with the procedure where there is a steady flow (S) of process gas to the reaction chamber.

1. A semiconductor manufacturing apparatus, the apparatus comprising:
a reaction chamber;
one or more gas inlets to said reaction chamber; and;
two or more accumulators connected to at least one of said one or more gas inlets;
wherein said two or more accumulators are connected in parallel to each other.

2. The semiconductor manufacturing apparatus according to claim 1, wherein said apparatus further comprises a solid-state precursor sublimator upstream from said two or more accumulators.

3. The semiconductor manufacturing apparatus according to claim 1, wherein a combined volume of said two or more accumulators ranges between 10 liters and 200 liters.

4. The semiconductor manufacturing apparatus according to claim 3, wherein a volume of each of said two or more accumulators is equal.

5. The semiconductor manufacturing apparatus according to claim 3, wherein a volume of at least two of said two or more accumulators is different.

6. The semiconductor manufacturing apparatus according to claim 1, wherein said semiconductor manufacturing apparatus comprises a conduct line upstream and downstream from said two or more accumulators, said conduct line comprising a conduct line valve.

7. The semiconductor manufacturing apparatus according to claim 1, wherein said apparatus further comprises a controller comprising program instructions for:
accumulating a process gas in said two or more accumulators until each of said accumulators is at an accumulator pressure level which is substantially greater than the pressure level in said reaction chamber; and
rapidly discharging said process gas from at least one of said two or more accumulators into said reaction chamber.

8. The semiconductor manufacturing apparatus according to claim 7, wherein said process gas comprises a vaporized liquid or solid precursor compound comprising a metal or a metalloid.

9. The semiconductor manufacturing apparatus according to claim 8, wherein said precursor compound includes at least one compound chosen from Titanium tetrachloride (TiCl₄), Vanadium tetrachloride (VCl₄), Molybdenum pentachloride (MoCl₅), Molybdenumdioxidichloride (MoO₂Cl₂), Niobiumpentachloride (NbCl₅), Tantalumpentachloride (TaCl₅), Aluminumtrichloride (AlCl₃), Hafniumtetrachloride (HfCl₄), Zirconiumtetrachloride (ZrCl₄), Tetrakis(ethylmethylamido)zirconium (TEMAZr) or Tetrakis(ethylmethylamido)hafnium (TEMAHf) Trimethylborate (TMB), Fluorotriethoxysilane (FTES), Tetrakis-dimethylamino Titanium (TDMAT), Tetrakis-diethylamino (TDEAT), CuTMVS, Diethylsilane, and Triethylphosphate (TEPO).

10. The semiconductor manufacturing apparatus according to claim 7, wherein said controller comprises program instructions for alternatingly accumulating and discharging process gas in and from said two or more accumulators wherein process gas is accumulating in a first accumulator while process gas is discharged from a second accumulator, and wherein process gas is accumulating in a second accumulator when process gas is discharged from said first accumulator.

11. The semiconductor manufacturing apparatus according to claim 7, wherein said semiconductor manufacturing apparatus is a vertical furnace and said reaction chamber is configured for receiving batch of wafers accommodated in a wafer boat.

12. Method for delivering a process gas to a reaction chamber for the manufacturing of a semiconductor, the method comprising the steps of:
accumulating a process gas in two or more accumulators until each of said accumulators is at an accumulator pressure level which is substantially greater than the pressure level in said reaction chamber; and
rapidly discharging said process gas from at least one of said two or more accumulators into said reaction chamber;
wherein said two or more accumulators are connected in parallel to each other.

13. The method according to claim 12, wherein said process gas comprises a vaporized liquid or solid precursor compound comprising a metal or a metalloid.

14. The method according to claim 13, wherein said precursor compound includes at least one compound chosen from Titanium tetrachloride (TiCl₄), Vanadium tetrachloride (VCl₄), Molybdenum pentachloride (MoCl₅), Molybdenumdioxidichloride (MoO₂Cl₂), Niobiumpentachloride (NbCl₅), Tantalumpentachloride (TaCl₅), Aluminumtrichloride (AlCl₃), Hafniumtetrachloride (HfCl₄), Zirconiumtetrachloride (ZrCl₄), Tetrakis(ethylmethylamido)zirconium (TEMAZr) or Tetrakis(ethylmethylamido)hafnium (TEMAHf), Trimethylborate (TMB), Fluorotriethoxysilane (FTES), Tetrakis-dimethylamino Titanium (TDMAT), Tetrakis-diethylamino (TDEAT), CuTMVS, Diethylsilane, and Triethylphosphate (TEPO).

15. The method according to claim 12, wherein the steps of accumulating and discharging said process gas occur alternatingly, thereby accumulating process gas in a first accumulator while process gas is discharged from a second accumulator, and accumulating process gas in a second accumulator when process gas is discharged from said first accumulator.
